(19) United States
(12) Patent Application Publication
(10) Pub. No.: US 2025/0253196 A1
(43) Pub. Date: Aug. 7, 2025

(54) HERMETIC SMD PACKAGE

(71) Applicant: Microchip Technology Incorporated, Chandler, AZ (US)

(72) Inventors: Saeed Shafiyan-rad, Nashua, NH (US); Thomas Doughty, North Andover, MA (US); Evan Kirk, Salisbury, MA (US)

(73) Assignee: Microchip Technology Incorporated, Chandler, AZ (US)

(21) Appl. No.: 18/635,815

(22) Filed: Apr. 15, 2024

Related U.S. Application Data
(60) Provisional application No. 63/548,816, filed on Feb. 1, 2024.

(51) Int. Cl. H01L 23/10; H01L 23/00; H01L 23/057; H01L 25/065

(52) U.S. Cl. CPC H01L 23/10; H01L 23/057; H01L 24/08; H01L 24/48; H01L 25/0652; H01L 2224/08145; H01L 2224/08225; H01L 2224/48137; H01L 2224/48138; H01L 2924/01029; H01L 2924/01074; H01L 2924/13091; H01L 2924/1611

(57) ABSTRACT

A device including a substrate having a first aperture, a second aperture and a third aperture. Where a bottom surface of the first and second covers may be bonded to the top surface of substrate to cover the first and second apertures, respectively, and with first and second leads bonded to the bottom surface of the first and second covers, respectively, so the first and second leads extend through the first and second apertures, respectively. The top surface of a third cover may be bonded to the bottom surface of the substrate to cover the third aperture. The bottom portion of a seal ring may be bonded to the top portion of the substrate to surround the first, second, and third apertures, and a cap may be bonded to the top portion of the seal ring. The components may be bonded to create hermetic seals for an SMD package.

### PRIORITY

This application claims priority to U.S. Provisional Application No. 63/548,816 filed Feb. 1, 2024, the entire contents of which is incorporated herein by reference for all purposes.

### TECHNICAL FIELD

The present disclosure relates to hermetically sealed surface-mount device (SMD) packages.

### BACKGROUND

Surface-mount devices (SMDs) include electronic devices that allow electronic components to be mounted onto the surface of a printed circuit board (PCB). An SMD typically includes a package that surrounds, encloses, or otherwise carries one or more electronic components and provides electrical connections between the PCB and the electronic components of the package (e.g., source, gate, and drain connections). Electronic components, such as diodes, transistors, power transistors, MOSFETs, JFETs, resistors, capacitors, inductors, other semiconductor devices, and the like, may be exposed to extreme environmental conditions in certain applications, e.g., for use in space. Such components may require hermetic seals. MOSFETs, diodes, and capacitors may be certified for high temperatures (e.g., 300° C.) and used in deep-space science and human exploration missions. Such missions may employ radiation-hardened, extreme-temperature components and interconnects. For example, capabilities specified for NASA missions include extreme-temperature, radiation-hardened, high-voltage components.

SMD packages suitable for use in extreme environments such as space, may include high voltage handling capability (e.g., hundreds of volts), high current handling capability (e.g., 20 amps or more), hermetic seals meeting JANS level specifications, low inductance, low impedance, high thermal conductivity, high flexibility in terms of heatsink capability, including multiple points of thermal conduction contacts, high isolation voltage capability for space applications (high altitude and near perfect vacuum environments), light weight relative to standard commercial copper based packages, capability to meet JANS space level HiRel screening and long term reliability testing, capability to support electronics in a high radiation/harsh environments, physical ruggedness to withstand harsh conditions experienced in launch vehicles, and scalability and dimensional flexibility to accommodate different electronic components such as silicon, silicon carbide, gallium nitride, gallium-arsenide, or other semiconductor die components and the like. It may also be radiation-hardened and hermetically sealed to prevent radiation or other environmental factors (e.g., moisture, corrosion, and contamination) from impacting operation of the device.

SMD packages in these extreme environments, may experience extreme stress from the different coefficients of thermal expansion (CTE) of different materials. For example, stress may occur between the printed circuit board (PCB) and the hermetically sealed package, between the hermetically sealed package and the mounting substrates, and between the mounting substrates and the semiconductor die. Components mounted or attached to each other and made of different materials having a different coefficient of thermal expansion (CTE) may experience high stress when temperatures change. Cracking related to CTE mismatch in current SMD packages has been observed and reported by NASA's Jet Propulsion Laboratory in a presentation titled “SMD Package Crack Susceptibility Issue,” available at: https://ntrs.nasa.gov/citations/20220009470. NASA found that current SMD packages may crack when mounted to a PCB and temperature cycled. NASA noted the observed cracking issues in SMD packages leads to a loss of hermeticity, which could cause electrical failures, e.g., due to moisture, corrosion, and contamination.

Examples of the present disclosure may address one or more of these issues.

### SUMMARY

Aspects and examples of the present disclosure provide for a hermetically sealed package for SMDs that reduces susceptibility to cracking and loss of hermeticity due to thermally induced stress related to CTE mismatch of different materials and thermal cycling.

One aspect may include a device. For example, the device may include a substrate having a top surface, a bottom surface, a first aperture, a second aperture and a third aperture. The device may further include a first cover having a top surface and a bottom surface, the bottom surface of the first cover bonded to the top surface of the substrate and covering the first aperture in the substrate. The device may further include a second cover having a top surface and a bottom surface, the bottom surface of the second cover bonded to the top surface of the substrate and covering the second aperture in the substrate. The device may further include a first lead bonded to the bottom surface of the first cover, the first lead extending through the first aperture in the substrate, and a second lead bonded to the bottom surface of the second cover, the second lead extending through the second aperture in the substrate. The device may further include a third cover having a top surface and a bottom surface, the top surface of the third cover bonded to the bottom surface of the substrate and covering the third aperture in the substrate. The device may further include a seal ring having a top portion and a bottom portion, the bottom portion of the seal ring bonded to the top surface of the substrate to surround the first, second, and third apertures, and a cap bonded to the top portion of the seal ring.

Another aspect may include a method. For example, the method may include bonding a bottom surface of a first cover to a top surface of a substrate to cover and hermetically seal a first aperture in the substrate, and bonding a bottom surface of a second cover to the top surface of the substrate to cover and hermetically seal a second aperture in the substrate. The method may also include, bonding a top surface of a third cover to a bottom surface of the substrate to cover and hermetically seal a third aperture in the substrate. The method may also include bonding a bottom portion of a seal ring to the top surface of the substrate, the seal ring surrounding the first, second, and third apertures, and bonding a cap to a top portion of the seal ring to hermetically seal a space within the seal ring and between the substrate and the cap.

Another aspect may include a system. For example, the system may include a hermetically sealed surface-mount device package. The hermetically sealed surface-mount device package may include a substrate having a top surface, a bottom surface, a first aperture, a second aperture and a third aperture; a first cover having a top surface and a bottom surface, the bottom surface of the first cover bonded to the top surface of the substrate to cover the first aperture in the substrate and to hermetically seal the first aperture; a second cover having a top surface and a bottom surface, the bottom surface of the second cover bonded to the top surface of the substrate to cover the second aperture in the substrate and to hermetically seal the second aperture; a first end of a first lead bonded to the bottom surface of the first cover, the first lead extending through the first aperture in the substrate; a first end of a second lead bonded to the bottom surface of the second cover, the second lead extending through the second aperture in the substrate; a third cover having a top surface and a bottom surface, the top surface of the third cover bonded to the bottom surface of the substrate to cover the third aperture in the substrate and to hermetically seal the third aperture; a pad bonded to the bottom surface of the third cover; a seal ring having a top portion and a bottom portion, the bottom portion of the seal ring bonded to the top surface of the substrate to surround the first, second, and third apertures; and a cap bonded to the top portion of the seal ring to hermetically seal a first space within the seal ring and between the substrate and the cap. The system may also include a semiconductor die disposed within the first space.

### BRIEF DESCRIPTION OF THE DRAWINGS

The figures illustrate aspects of hermetically sealed SMD packages of the present disclosure.

FIG. 1 shows a hermetic SMD package with L-shaped leads.

FIG. 2A shows a perspective view of a hermetic SMD package with C-shaped leads.

FIG. 2B shows a cutaway side view of a hermetic SMD package with C-shaped leads.

FIG. 3 shows a hermetic SMD package with C-shaped leads.

FIG. 4 shows a system including a hermetic SMD package, semiconductor die, and printed circuit board.

FIG. 5 shows a method of manufacturing a hermetic SMD package.

FIG. 6 shows a method of manufacturing a hermetic SMD package.

The reference number for illustrated elements that appears in multiple different figures has the same meaning across the multiple figures, and the mention or discussion herein of any illustrated element in the context of any particular figure also applies to each other figure, if any, in which that same illustrated element is shown. In some figures, certain elements may be omitted for clarity when discussing aspects or examples of other elements.

### DESCRIPTION

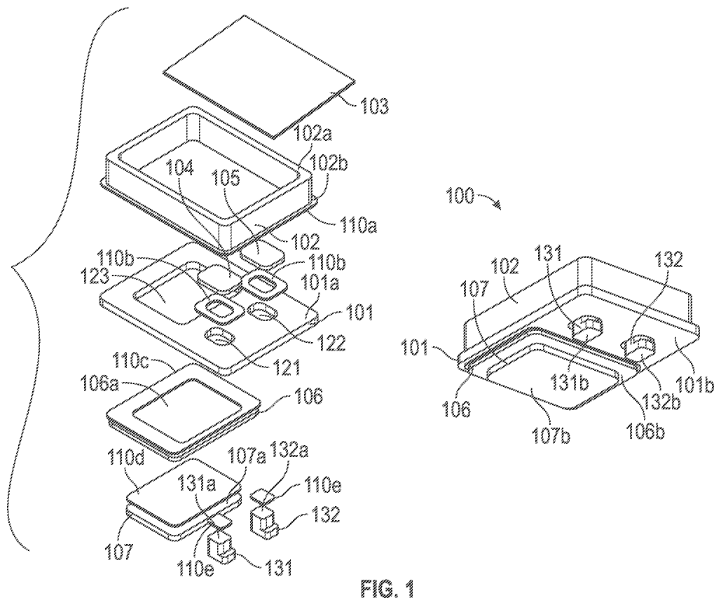

Referring to FIG. 1, there is provided an assembled and an exploded view of a hermetically sealed SMD package 100. SMD package 100 may include a substrate 101 that provides a base for SMD package 100. Substrate 101 may include a top surface 101a (visible in the exploded view), a bottom surface 101b (visible in the assembled view), a first aperture 121, a second aperture 122, and a third aperture 123. In some examples, substrate 101 may generally be an electrically and thermally insulating material. In some examples, substrate 101 may be a ceramic material (e.g., zirconium oxide, silicon nitride, without limitation), a composite material (e.g., zirconia toughened alumina (ZTA), without limitation), or any other suitable material to form the base substrate for SMD package 100. First, second and third apertures 121, 122, and 123 may allow electrical connections to be made through the substrate 101, e.g., for source, gate, and drain connections. Although the example of FIG. 1 includes three apertures, first, second and third apertures 121, 122, and 123, various examples of substrate 101 may include more or fewer apertures, depending on the application. Although first, second and third apertures 121, 122, and 123 are shown to have a generally rectangular shape, any other suitable shape may be used (e.g., circular, without limitation). SMD package 100 may include seal ring 102, a bottom portion 102b of seal ring 102 may be bonded to the top surface 101a of substrate 101 and which seal ring 102 forms the sidewall structure for SMD package 100. In some examples, the bottom portion 102b of seal ring 102 may comprise a flange portion to provide a seat for seal ring 102. The term ring as used herein is not intended to limit the geometric shape of seal ring 102. Seal ring 102 may be generally rectangular in shape (as shown) or may be any other suitable geometry, e.g., generally circular, elliptical, or irregularly shaped, without limitation. Seal ring 102 may surround first, second and third apertures 121, 122, and 123. Seal cap 103 may be bonded to the top portion 102a of seal ring 102 to form an upper enclosure for SMD package 100, which may house an electronic component, such as a semiconductor die (not shown) and may be surface mounted to a PCB (not shown). In some examples, the outer permitter of cap 103 may include a flange portion to provide a seat for seal cap 103. In some examples, the top portion 102a of seal ring 102 may comprise a flange portion to provide a seat for seal cap 103. Although SMD package 100 is shown as generally a rectangular cubic structure, the shape shown is not intended to limit the package shape and other shapes (e.g., cylindrical, without limitation) may be used. Seal ring 102 and cap 103 may be of the same or different materials, which may be a ceramic material, a composite material, a metallic material (e.g., iron-nickel-cobalt alloy such as ASTM F15 (Kovar), without limitation), or other suitable material with an appropriate CTE. In some respects, the CTE may be considered appropriate if it is substantially similar to the CTE of other components or provides a gradual transition in CTE to avoid a detrimental mismatch in CTE values between bonded components at locations of maximum or relatively high thermal stress. In some examples, SMD package 100 may utilize ceramics with higher thermal conductivity and increased strength/toughness compared to other ceramics to allow functionality in a smaller size package.

SMD package 100 may include a first cover 104 and second cover 105. Cover 104 may include a top surface 104a (visible in the exploded view) and a bottom surface (not visible). Cover 105 may include a top surface 105a (visible in the exploded view) and a bottom surface (not visible). The bottom surface of cover 104 may be bonded to the top surface 101a of substrate 101 to cover the first aperture 121 in substrate 101. The bottom surface of cover 105 may be bonded to the top surface 101a of substrate 101 to cover the second aperture 122 in substrate 101. First and second covers 104 and 105 may be sized and positioned to respectively cover apertures 121 and 122 in substrate 101. First and second covers 104 and 105 may be a metallic material, which may include metal matrix composite materials, with an appropriate electrical conductivity and CTE, e.g. a copper-tungsten alloy or other suitable material, without limitation. First and second covers 104 and 105 may be used to electrically couple (e.g., with bond wires attached to the top surfaces 104a and 105a, respectively, of first and second covers 104 and 105) corresponding source and gate terminals of an electronic component, such as a semiconductor die (not shown), that may be housed inside SMD package 100. In some examples, first cover 104 may be referred to as a source cover and second cover 105 may be referred to as a gate cover or vice versa depending on the application.

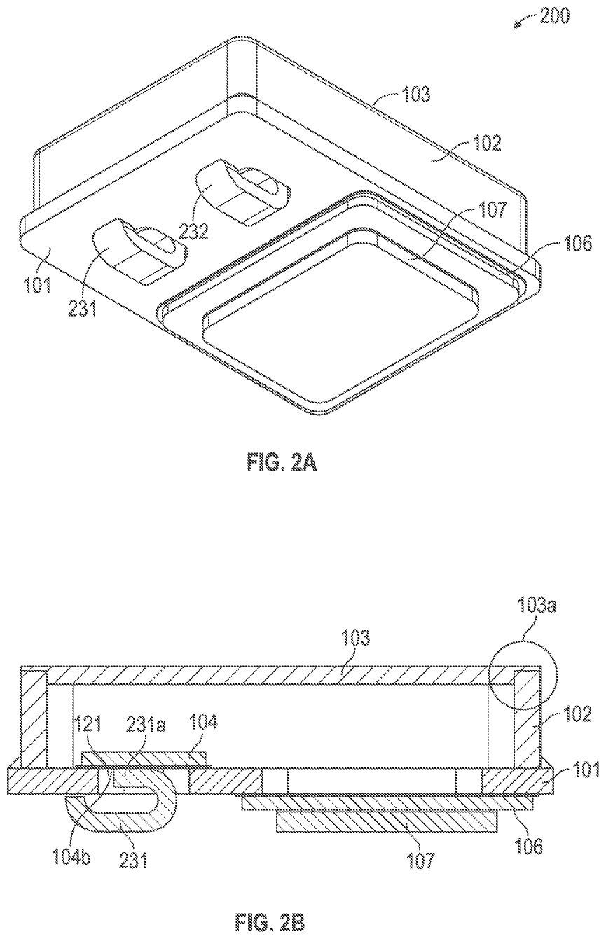

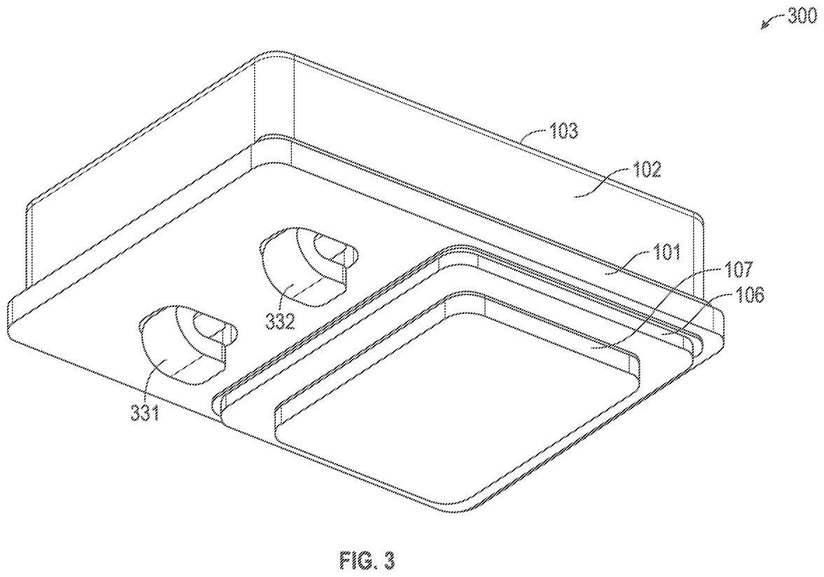

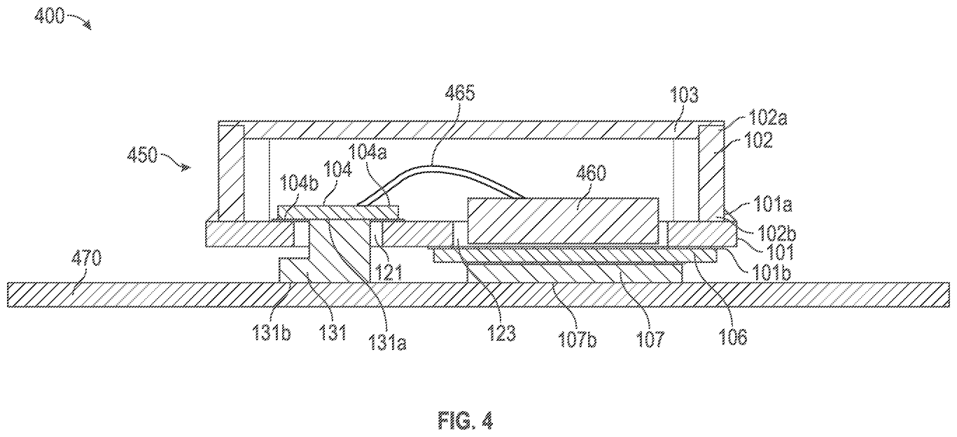

SMD package 100 may include a first lead 131 and a second lead 132. The top surface 131a (visible in the exploded view) of first lead 131 may be bonded to the bottom surface of first cover 104 and first lead 131 may extend through aperture 121 in substrate 101. The top surface 132a (visible in the exploded view) of second lead 132 may be bonded to the bottom surface of second cover 105 and second lead 132 may extend through aperture 122 in substrate 101. First and second leads 131 and 132 may be L-shaped (e.g., as shown in FIG. 1), C-shaped (e.g., as shown in FIGS. 2 and 3), straight, or other suitable geometries. First and second leads 131 and 132 may be used to thermally and electrically couple first and second covers 104 and 105, respectively, to a PCB (not shown), e.g., by soldering or otherwise bonding the bottom surfaces 131b and 132b (visible in the assembled view) of first and second leads 131 and 132 to corresponding locations on the PCB. Bottom surfaces 131b and 132b may also be referred to as second ends 131b and 132b. In some examples, first lead 131 may be electrically coupled to a source connection of a PCB and second lead 132 may be electrically coupled to a gate connection of a PCB. In some examples, first lead 131 may be used to make the gate connection and second lead 132 to make the source connection to a PCB. First and second leads 131 and 132 may be a metallic material such as oxygen-free high thermal conductivity copper, copper alloy, or other suitable materials with appropriate thermal and electrical properties. Oxygen-free high thermal conductivity copper includes a group of copper alloys that have been refined to reduce the oxygen levels. In some examples, oxygen levels are below 0.05%. In other examples, the oxygen levels are below 0.005%. In yet other examples, oxygen levels are at or below 0.0005%. In some examples, electrical conductivity may exceed 100% of the International Annealed Copper Standard. In various examples, high thermal conductivity may denote a thermal conductivity more than 200 BTU/ft·h·° F.

SMD package 100 may include a third cover 106. Third cover 106 may have a top surface 106a (visible in the exploded view) and a bottom surface 106b (visible in the assembled view). The top surface 106a of third cover 106 may be bonded to the bottom surface 101b of substrate 101. Third cover 106 may be sized and positioned to cover third aperture 123 in substrate 101. Third cover 106 may be a metallic material, which may include metal matrix composite materials, with an appropriate electrical conductivity and CTE (e.g. a copper-tungsten alloy) or other suitable material. In some examples, third cover 106 may be made of the same material as first and second covers 104 and 105. Third cover 106 may be used to electrically couple (e.g., with bond wires or other suitable techniques) a corresponding drain terminal of an electronic component, such as a semiconductor die (not shown), that may be housed inside SMD package 100. In some examples, third cover 106 may be referred to as a drain cover. The electronic component (e.g., a semiconductor die or other component, not shown) may be mounted, directly or indirectly, to the top surface 106a of third cover 106 or the top surface 101a of substrate 101. In this manner, the electronic component may be housed within SMD package 100. Pad 107 may have a top surface 107a (visible in the exploded view) and a bottom surface 107b (visible in the assembled view). The top surface 107a of pad 107 may be bonded to the bottom surface 106b of third cover 106. Pad 107 may be a metallic material such as oxygen-free high thermal conductivity copper, copper alloy, or other suitable material. In some examples, pad 107 may be made of the same material as first and second leads 131 and 132. In some examples, pad 107 may be used to make a drain connection to a PCB (not shown). Pad 107 may be used to thermally and electrically couple third cover 106 to a PCB, e.g., by soldering or otherwise bonding the bottom surface 107b of pad 107 to the PCB. In some examples, pad 107 may be referred to as a drain pad. In some examples, the combination of third cover 106 and pad 107 may be referred to as a drain pad assembly. Although first, second and third covers 104, 105, and 106 are shown to have a generally rectangular shape, any other suitable geometry may be used.

In some aspects, bonding of components may include, but is not limited to, brazing, soldering, welding, or the use of an epoxy or other suitable adhesive material, depending on the connection being made and whether electrical or thermal coupling is desired. For example, bonding materials 110a-110e may be used to hermetically seal SMD package 100. Bonding material 110a may be used to bond and hermetically seal the bottom portion 102b of seal ring 102 to the top surface 101a of substrate 101. Bonding materials 110b may be used to bond the bottom surfaces 104b and 105b of first and second covers 104 and 105, respectively, to the top surface 101a of substrate 101 such that first and second covers 104 and 105 cover and hermetically seal first and second apertures 121 and 122, respectively. Bonding material 110c may be used to bond the top surface 106a of third cover 106 to the bottom surface 101b of substrate 101 such that cover 106 covers and hermetically seals third aperture 123. Bonding material 110d may be used to bond the top surface 107a of pad 107 to the bottom surface 106b of third cover 106, thereby creating a drain pad assembly. Bonding materials 110e may be used to bond the top surfaces 131a and 132a of first and second leads 131 and 132, respectively, to the bottom surfaces 104b and 105b of covers 104 and 105, respectively, thereby allowing first and second leads 131 and 132 to pass through first and second apertures 121 and 122 in substrate 101 without directly contacting substrate 101. Top surfaces 131a and 132a may also be referred to as first ends 131a and 132a. In some examples, bonding materials 110a-110e may be comprised of a braze filler metal, including but not limited to alloys comprised of aluminum-silicon, copper-phosphorus, silver, copper, copper-silver (e.g., Cusil), copper-zinc, magnesium, nickel, or cobalt, without limitation. In other examples, bonding materials 110a-110e may be comprised of weld filler metal or an adhesive material, e.g., epoxy, without limitation. The same or different bonding materials may be used to create a hermetic seal for different connections. For example, the bond material (not shown) used to bond the top portion 102a of seal ring 102 to cap 103 or bonding material 110a may be the same or different from bond material 110b used to bond first and second covers 104 and 105 to substrate 101.

In operation, hermetically sealed SMD package 100 and its various components may expand or contract based on the temperature differential and the CTE of the materials. Different materials of the package may have different values of CTE. The composition of materials in the package of various examples may provide for a substantially similar CTE or a gradual change in CTE across the different bonded components of the package and reduce the stress caused by thermal cycling. In addition to using materials with appropriate CTE values, bonding bottom surfaces 104b and 105b of first and second covers 104 and 105, respectively, to the top surface 101a of substrate 101 (rather than to the bottom surface 101b of substrate 101) and extending first and second leads 131 and 132 through substrate 101 without directly contacting substrate 101 may provide a significant reduction in maximum stress due to thermal cycling when SMD package 100 is used in extreme environments, such as space applications. Stress may be further reduced by using different geometries for the leads and the drain pad assembly and the present disclosure is not limited to the specific geometries shown.

Referring to FIGS. 2A and 2B, a perspective view (2A) and a cutaway side view (2B) of hermetically sealed SMD package 200 are provided. Like numerals correspond to like components of SMD package 100 from FIG. 1 as described above, and corresponding descriptions are not repeated for brevity. Rather than using the L-shaped first and second leads 131 and 132 of FIG. 1, FIGS. 2A and 2B show an example using C-shaped first and second leads 231 and 232. Including one or more bends in C-shaped first and second leads 231 and 232 may further reduce the stresses during thermal cycling. As shown in FIG. 2B, and like first and second leads 131 and 132 of FIG. 1, the top surface 231a of first lead 231 is bonded to the bottom surface 104b of first cover 104, and first lead 231 extends through first aperture 121 in substrate 101. Similarly, the top surface (not visible) of second lead 232 is bonded to the bottom surface (not visible) of second cover 105, and second lead 232 extends through second aperture (not visible) in substrate 101. In some examples, the outer permitter of cap 103 may include a flange portion indicated by 103a to provide a seat for seal cap 103 as shown in FIG. 2B.

Referring to FIG. 3, a perspective view of hermetically sealed SMD package 300 is provided. Like numerals correspond to like components of SMD package 100 from FIG. 1 as described above, and corresponding descriptions are not repeated for brevity. FIG. 3 includes C-shaped first and second leads 331 and 332, which have a different geometry and orientation than C-shaped first and second leads 231 and 232 of FIG. 2. First and second leads 331 and 332 include a single bend with the opening facing toward third cover 106, whereas first and second leads 231 and 232 include multiple bends with the opening facing away from third cover 106. In some examples, C-shaped leads may include more or fewer bends and may be oriented with an opening facing in any direction.

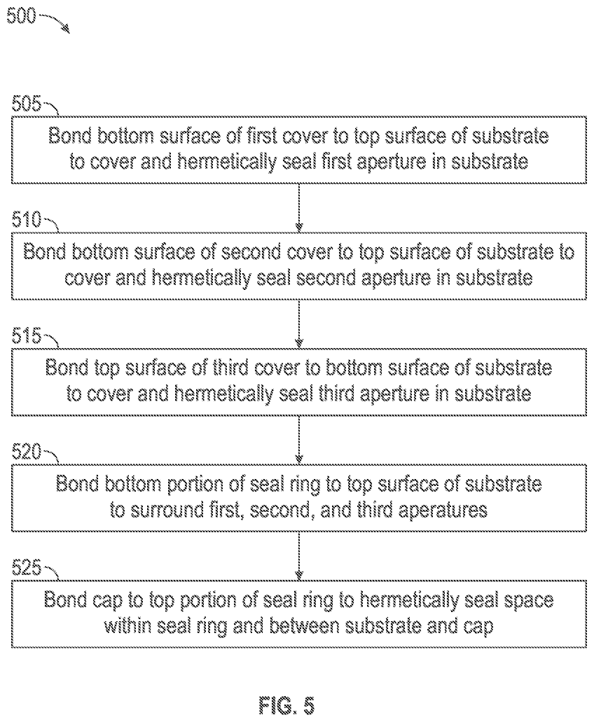

Referring to FIG. 4, a cutaway side view of a system 400 is provided. System 400 includes hermetically sealed SMD package 450, semiconductor die 460 and printed circuit board (PCB) 470. SMD package 450 may be implemented in the same manner as SMD package 100 of FIG. 1, SMD package 200 of FIG. 2, or SMD package 300 of FIG. 3. Like numerals correspond to like components of SMD package 100 from FIG. 1 as described above, and corresponding descriptions are not repeated for brevity. Some features of SMD package 450 are not shown in FIG. 4 because FIG. 4 is a cutaway side view.

As described for FIG. 1, hermetically sealed SMD package 450 of FIG. 4 includes a substrate 101 having a top surface 101a, a bottom surface 101b, and three apertures. Apertures 121 and 123 are visible in FIG. 4, while aperture 122 is not visible in the cutaway side view of FIG. 4. The bottom surface 104b of a first cover 104 may be bonded to the top surface 101a of substrate 101 to cover first aperture 121 and to hermetically seal first aperture 121. The bottom surface 105b of a second cover 105 (not shown) may be bonded to the top surface 101a of substrate 101 to cover second aperture 122 (not shown) and to hermetically seal second aperture 122. A first end 131a of first lead 131 may be bonded to the bottom surface 104b of first cover 104 and first lead 131 may extend through first aperture 121. The first end 131a of first lead 131 may also be referred to as a top surface of first lead 131. A first end of second lead 132 (not shown) may be bonded to the bottom surface 105b of second cover 105 (not shown) and second lead 132 may extend through second aperture 122. The first end of second lead 132 may also be referred to as a top surface of second lead 132. First and second leads 131 and 132 may be L-shaped (as shown), C-shaped (as shown in FIGS. 2 and 3), or any other suitable geometry. The top surface 106a of third cover 106 may be bonded to the bottom surface 101b of substrate 101 to cover third aperture 123 and to hermetically seal third aperture 123. The bottom portion 102b of seal ring 102 may be bonded to the top surface 101a of substrate 101 in a manner that creates a hermetic seal between seal ring 102 and substrate 101. Seal ring 102 may surround first, second and third apertures 121, 122, and 123. Cap 103 may be bonded to a top portion 102a of seal ring 102 to hermetically seal a space formed within seal ring 102 and between substrate 101 and cap 103. Semiconductor die 460 may be disposed within the space within seal ring 102 and between substrate 101 and cap 103 as shown.

Semiconductor die 460 may be a MOSFET device, a Gallium-Nitride device, a Gallium-Arsenide device, or any other electronic device comprised of a semiconductor material. Semiconductor die 460 may function as a power transistor, a processor, or any other type of electronic function. In one example, semiconductor die 460 may include a source connection, a gate connection, and a drain connection. The top surface 104a of cover 104 may be electrically coupled to the source connection of semiconductor die 460 using any suitable electrical connection. For example, without limitation, a bond wire 465 may be used to electrically couple the top surface 104a of cover 104 to the source connection of semiconductor die 460. Although the example of FIG. 4 shows a single bond wire 465, in various examples more than one bond wire may be used. Similarly, the top surface 105a of cover 105 (not shown) may be electrically coupled to the gate connection of semiconductor die 460. The top surface 106a of cover 106 may be electrically coupled to the drain connection of semiconductor die 460. In one example, the bottom surface of semiconductor die 460 may be attached to the top surface 106a of cover 106 using a mounting layer (not shown). The mounting layer may provide a thermal and electrical connection between semiconductor die 460 and cover 106. The mounting layer may be comprised of a solder filler metal and may join semiconductor die 460 and cover 106 using a solder reflow process. In another example, the mounting layer may be comprised of a brazing filler metal and may join semiconductor die 460 and cover 106 using a brazing process. In other examples, additional mounting structures (not shown) may be disposed between semiconductor die 460 and cover 106. In various examples, electrical connections may be made using vias, bond wires, welding, soldering, brazing, or any other suitable techniques.

System 400 may also include PCB 470. In one example, a source connection of PCB 470 may be electrically coupled to the second end (or bottom surface) 131b of first lead 131. A gate connection of PCB 470 may be electrically coupled to the second end (or bottom surface) 132b of second lead 132 (not shown). A bottom surface 107b of pad 107 may be electrically coupled to a drain connection of PCB 470. In this manner, hermetically sealed SMD package 450 may be mounted to PCB 470. In some examples, SMD package 450 may be directly mounted to PCB 470. In other examples, a carrier may be used to mount SMD package 450 to PCB 470.

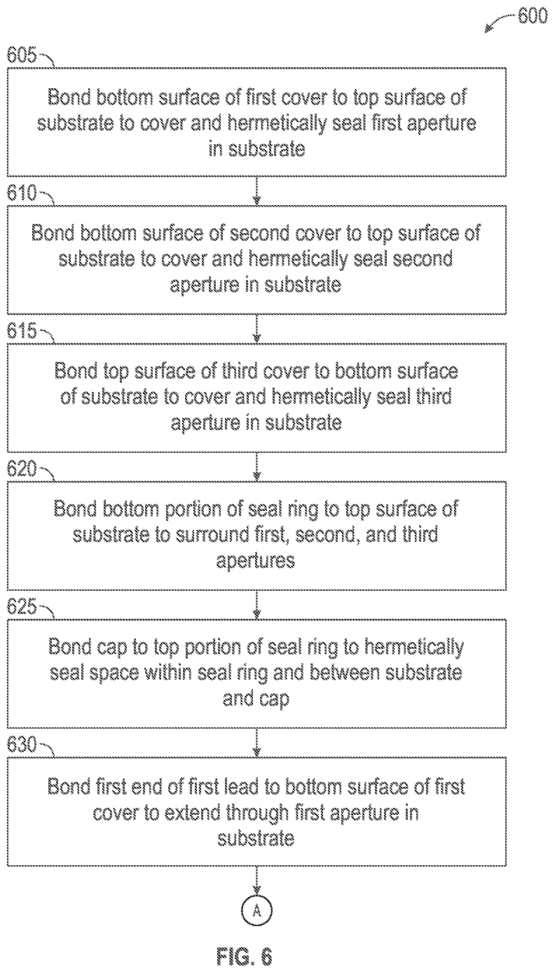

Referring to FIG. 5, a flow chart is provided of an example method 500 for making a hermetically sealed SMD package (e.g., SMD package 100, 200, 300, or 450) in accordance with the present disclosure. In some examples, the method 500 may be executed with more or fewer operations than shown in FIG. 5, and the operations shown in FIG. 5 may be optionally omitted, repeated, performed in a different order, performed in parallel, or recursively.

At 505, the bottom surface of a first cover (e.g., first cover 104) is bonded to the top surface of a substrate (e.g., substrate 101) to cover and hermetically seal a first aperture (e.g., first aperture 121) in the substrate. At 510, the bottom surface of a second cover (e.g., second cover 105) is bonded to the top surface of the substrate to cover and hermetically seal a second aperture (e.g., second aperture 122) in the substrate. At 515, the top surface of a third cover (e.g., third cover 106) is bonded to the bottom surface of the substrate to cover and hermetically seal a third aperture (e.g., third aperture 123) in the substrate. At 520, the bottom portion of a seal ring (e.g., seal ring 102) is bonded to the top surface of the substrate, the seal ring surrounding the first, second, and third apertures. At 525, a cap (e.g., cap 103) is bonded to the top portion of the seal ring to hermetically seal a space within the seal ring and between the substrate and the cap.

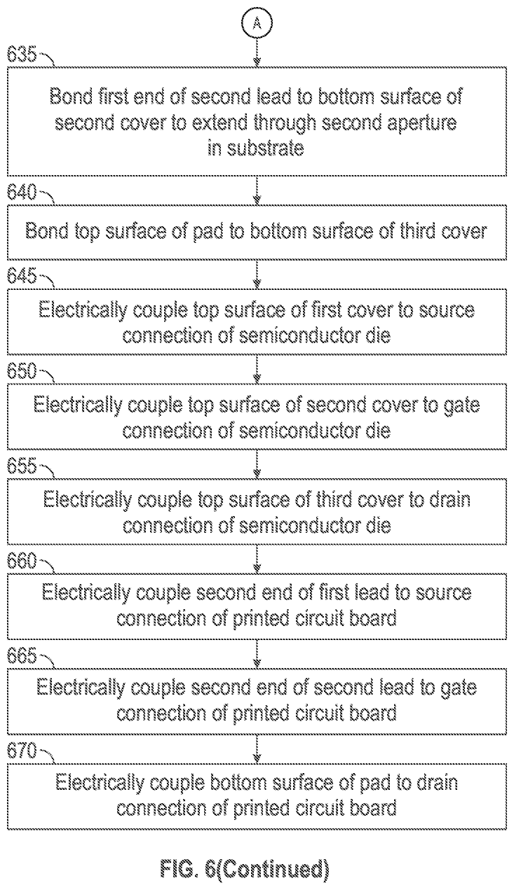

Referring to FIG. 6, a flow chart is provided of an example method 600 for making a system including a hermetically sealed SMD package (e.g., SMD package 100, 200, 300, or 450), and semiconductor die, and a PCB, in accordance with the present disclosure. In some examples, the method 600 may be executed with more or fewer operations than shown in FIG. 6, and the operations shown in FIG. 6 may be optionally omitted, repeated, performed in a different order, performed in parallel, or recursively. For example, the bonding of the seal ring at 620 or cap at 625 may occur after electrical connections are made for the semiconductor die at 645-655. The order of performing various operations may vary depending on manufacturing preferences or constraints.

Blocks 605-625 of method 600 correspond to blocks 505-525 of method 500 as described above and are not repeated for brevity. At 630, the first end (or top surface) of a first lead (e.g., first lead 131, 231, or 331) is bonded to the bottom surface of the first cover (e.g., first cover 104). At 635, the first end (or top surface) of a second lead (e.g., second lead 132, 232, of 332) is bonded to the bottom surface of the second cover (e.g., second cover 105). At 640, the top surface of a pad (e.g., pad 107) is bonded to the bottom surface of the third cover (e.g., third cover 106). At 645, the top surface of the first cover is electrically coupled to a source connection of a semiconductor die (e.g., semiconductor die 460). At 650, the top surface of the second cover is electrically coupled to a gate connection of the semiconductor die. At 655, the top surface of the third cover is electrically coupled to a drain connection of the semiconductor die. At 660, the second end (or bottom surface) of the first lead is electrically coupled to a source connection of a printed circuit board (e.g., PCB 470). At 665, the second end (or bottom surface) of the second lead is electrically coupled to a gate connection of the printed circuit board. At 670, the bottom surface of the pad is electrically coupled to a drain connection of the printed circuit board. In this manner, a hermetically sealed SMD package containing a semiconductor die may be mounted to a PCB and may result in reduced maximum stresses due to thermal expansion and contraction during thermal cycles.

Regarding Methods 500 and 600, and as explained with reference to FIGS. 1-4, in some examples, the substrate (e.g., substrate 101) may be a ceramic material (e.g., zirconium oxide, silicon nitride, without limitation), a composite material (e.g., zirconia toughened alumina (ZTA), without limitation), or any other suitable material to form the base substrate for a SMD package. The seal ring (e.g., seal ring 102) and cap (e.g., cap 103) may be of the same or different materials, which may be a ceramic material, a composite material, a metallic material (e.g, iron-nickel-cobalt alloy such as ASTM F15 (Kovar), without limitation), or other suitable material with an appropriate CTE. First, second, and third covers (e.g., first, second and third covers 104, 105, and 106) may be a metallic material, which may include metal matrix composite materials, with an appropriate electrical conductivity and CTE, e.g. a copper-tungsten alloy or other suitable material, without limitation. The first and second leads (e.g., first and second leads 131 and 132) and the drain pad (e.g., drain pad 107) may be a metallic material such as oxygen-free high thermal conductivity copper, copper alloy, or other suitable materials with appropriate thermal and electrical properties. In some aspects, bonding of components may include, but is not limited to, brazing, soldering, welding, or the use of an epoxy or other suitable adhesive material, depending on the connection being made and whether electrical or thermal coupling is desired. In some examples, bonding materials (e.g., bonding materials 110a-110e) may be used and may be comprised of a braze filler metal, including but not limited to alloys comprised of aluminum-silicon, copper-phosphorus, silver, copper, copper-silver (e.g., Cusil), copper-zinc, magnesium, nickel, or cobalt, without limitation. In other examples, bonding materials may be comprised of weld filler metal or an adhesive material, e.g., epoxy, without limitation.

In various examples disclosed herein, materials with appropriate values of CTE may be used for various components. In some examples, the CTE may be considered appropriate if it is substantially similar to the CTE of other components or provides a gradual transition in CTE to avoid a detrimental mismatch in CTE values between bonded components at locations of maximum or relatively high thermal stress. As the magnitude of thermal expansion (and thus thermal stress when constricted) is proportional to the change in temperature, components with greater changes in temperature during operation may have more similar values for CTE than components with lower relative changes in temperature. In some examples, materials in areas of maximum or relatively high thermal stress may be considered to have appropriate values of CTE if the difference in average values of CTE is less than 50%. In other examples, materials in areas of maximum or relatively high thermal stress may be considered to have a substantially similar CTE if the difference in average values of CTE is less than 25%. In yet other examples, materials in areas of maximum or relatively high thermal stress may be considered to have a substantially similar CTE if the difference in average values of CTE is less than 20%. The following table includes example ranges and average values of CTE (10⁴/° C.) for example materials of the present disclosure.

| | Low | High | Average |
|---|---|---|---|
| Zirconia | 9.0 | 11.0 | 10.0 |
| W85Cu15 | 6.5 | 9.0 | 7.8 |
| Copper | 16.8 | 17.9 | 17.4 |
| Kovar | 4.0 | 6.0 | 5.0 |
| Cusil | 18.0 | 20.0 | 19.0 |
| ZTA | 6.0 | 8.5 | 7.3 |

For example, one location of interest may be where the leads (e.g., leads 131 and 132) and drain pad (e.g., pad 107) connect with the substrate (e.g., via covers 104, 105, and 106). As an example, without limitation, the following materials may be considered to have appropriate CTE values for corresponding components of the SMD packages of the present disclosure (e.g., SMD packages 100, 200, 300, and 450). The substrate (e.g., substrate 101) may be comprised of zirconium oxide (a ceramic material also referred to as zirconia). The CTE for a given material may change with temperature. Example values of CTE for zirconium oxide may be in the range of 9×10⁻⁶/° C. to 11×10⁻⁶/° C. The covers (e.g., first, second, and third covers 104, 105, and 106) may be comprised of a copper-tungsten alloy such as W85Cu15. Example values of CTE for W85Cu15 may be in the range of 6.5×10⁴/° C. to 9×10⁻⁶/° C. This may provide an average difference in CTE on the order of 22% between the substrate and the covers. The first lead (e.g., 131, 231, or 331) and the second lead (e.g., 132, 232, or 332) and the drain pad (e.g., pad 107) may be comprised of oxygen free high thermal conductivity copper. Example values of CTE for oxygen free high thermal conductivity copper may be in the range of 16.8×10⁻⁶/° C. to 17.9×10⁻⁶/OC. If such copper were used for the covers (rather than W85Cu15) the average difference in CTE between the substrate and the covers would be on the order of 73%. By using a material with an appropriate CTE and electrical conductivity for the covers (e.g., W85Cu15), a gradual change in CTE between the copper leads and drain pad and the ceramic substrate may be achieved while allowing sufficient electrical current to pass through the covers to a semiconductor die housed within the SMD package. In combination with the geometries and arrangements of components as described herein, this may result in an overall decrease in thermal stress on the order of 20% or more compared to other arrangements and materials.

While the present disclosure has been described herein with respect to certain illustrated examples, those of ordinary skill in the art will recognize and appreciate that the claims appended hereto are not so limited. Rather, additions, deletions, and modifications to the illustrated and described examples may be made without departing from the spirit and scope of the present disclosure and aspects hereinafter claimed along with their legal equivalents. In addition, features from one example may be combined with features of another example while still being encompassed within the scope of the present disclosure as contemplated and described.

What is claimed is:

1. A device comprising:
a substrate having a top surface, a bottom surface, a first aperture, a second aperture, and a third aperture;
a first cover having a top surface and a bottom surface, the bottom surface of the first cover bonded to the top surface of the substrate and covering the first aperture in the substrate;
a second cover having a top surface and a bottom surface, the bottom surface of the second cover bonded to the top surface of the substrate and covering the second aperture in the substrate;
a first lead bonded to the bottom surface of the first cover, the first lead extending through the first aperture in the substrate;
a second lead bonded to the bottom surface of the second cover, the second lead extending through the second aperture in the substrate;
a third cover having a top surface and a bottom surface, the top surface of the third cover bonded to the bottom surface of the substrate and covering the third aperture in the substrate;
a seal ring having a top portion and a bottom portion, the bottom portion of the seal ring bonded to the top surface of the substrate to surround the first, second, and third apertures; and
a cap bonded to the top portion of the seal ring.

2. The device of claim 1, wherein:
the first cover and the second cover are bonded to the top surface of the substrate to hermetically seal the first and second apertures, respectively;
the third cover is bonded to the bottom surface of the substrate to hermetically seal the third aperture; and
the cap is bonded to the top portion of the seal ring to hermetically seal a space within the seal ring and between the substrate and the cap.

3. The device of claim 1, wherein at least the first cover, second cover, and third cover are bonded to the substrate via a respective brazed connection.

4. The device of claim 1, wherein the device is a hermetically sealed package to house a semiconductor die and to be surface mounted to a printed circuit board.

5. The device of claim 1, wherein the substrate comprises a ceramic material or a composite material.

6. The device of claim 5, wherein the substrate comprises silicon nitride, zirconium oxide, or zirconia toughened alumina.

7. The device of claim 1, wherein the first cover, the second cover, and the third cover comprise a copper-tungsten alloy.

8. The device of claim 1, wherein the seal ring and the cap comprise an iron-nickel-cobalt alloy.

9. The device of claim 1, comprising a pad bonded to the bottom surface of the third cover, wherein the first lead, the second lead, and the pad comprise an oxygen-free high thermal conductivity copper.

10. The device of claim 1, wherein the first lead and the second lead are L-shaped.

11. The device of claim 1, wherein the first lead and the second lead are C-shaped.

12. A method comprising:
bonding a bottom surface of a first cover to a top surface of a substrate to cover and hermetically seal a first aperture in the substrate;
bonding a bottom surface of a second cover to the top surface of the substrate to cover and hermetically seal a second aperture in the substrate;
bonding a top surface of a third cover to a bottom surface of the substrate to cover and hermetically seal a third aperture in the substrate;
bonding a bottom portion of a seal ring to the top surface of the substrate, the seal ring surrounding the first, second, and third apertures; and
bonding a cap to a top portion of the seal ring to hermetically seal a space within the seal ring and between the substrate and the cap.

13. The method of claim 12, comprising:
bonding a first end of a first lead to the bottom surface of the first cover, the first lead extending through the first aperture in the substrate;
bonding a first end of a second lead to the bottom surface of the second cover, the second lead extending through the second aperture in the substrate; and
bonding a pad to a bottom surface of the third cover.

14. The method of claim 13, comprising:
electrically coupling a top surface of the first cover to a source connection of a semiconductor die;
electrically coupling a top surface of the second cover to a gate connection of the semiconductor die; and
electrically coupling a top surface of the third cover to a drain connection of the semiconductor die.

15. The method of claim 12, wherein the substrate comprises silicon nitride, zirconium oxide, or zirconia toughened alumina.

16. The method of claim 13, wherein the first lead and the second lead are L-shaped or C-shaped.

17. A system comprising:
a hermetically sealed surface-mount device package, comprising:
a substrate having a top surface, a bottom surface, a first aperture, a second aperture and a third aperture;
a first cover having a top surface and a bottom surface, the bottom surface of the first cover bonded to the top surface of the substrate to cover the first aperture in the substrate and to hermetically seal the first aperture;
a second cover having a top surface and a bottom surface, the bottom surface of the second cover bonded to the top surface of the substrate to cover the second aperture in the substrate and to hermetically seal the second aperture;
a first end of a first lead bonded to the bottom surface of the first cover, the first lead extending through the first aperture in the substrate;
a first end of a second lead bonded to the bottom surface of the second cover, the second lead extending through the second aperture in the substrate;
a third cover having a top surface and a bottom surface, the top surface of the third cover bonded to the bottom surface of the substrate to cover the third aperture in the substrate and to hermetically seal the third aperture;
a pad bonded to the bottom surface of the third cover;
a seal ring having a top portion and a bottom portion, the bottom portion of the seal ring bonded to the top surface of the substrate to surround the first, second, and third apertures;
a cap bonded to the top portion of the seal ring to hermetically seal a first space within the seal ring and between the substrate and the cap; and
a semiconductor die disposed within the first space.

18. The system of claim 17, wherein:
the semiconductor die comprises a source connection, a gate connection, and a drain connection;
a top surface of the first cover is electrically coupled to the source connection of the semiconductor die;
a top surface of the second cover is electrically coupled to the gate connection of the semiconductor die; and
a top surface of the third cover is electrically coupled to the drain connection of the semiconductor die.

19. The system of claim 18, comprising:
a printed circuit board;
a source connection of the printed circuit board electrically coupled to a second end of the first lead;
a gate connection of the printed circuit board electrically coupled to a second end of the second lead; and
a bottom surface of the pad is electrically coupled to a drain connection of the printed circuit board.

20. The system of claim 17, wherein the first lead and second lead are L-shaped or C-shaped.
